(19) United States
(12) Patent Application Publication
(10) Pub. No.: US 2011/0197659 A1
(43) Pub. Date: Aug. 18, 2011

(54) METHOD FOR DETERMINING AN OVERALL LEAKAGE RATE OF A VACUUM SYSTEM AND VACUUM SYSTEM

(75) Inventors: Thomas Palten, Koeln (DE); Gerhard Wilhelm Walter, Kerpen (DE); Damian Ehrensperger, Basel (CH)

(73) Assignee: OERLIKON LEYBOLD VACUUM GMBH, KOELN (DE)

(21) Appl. No.: 13/057,774

(22) PCT Filed: Aug. 5, 2009
(86) PCT No.: PCT/EP2009/060169

§ 371 Date: Apr. 6, 2011

(30) Foreign Application Priority Data
Aug. 8, 2008 (DE) 10 2008 037 058.4

(51) Int. Cl. G01M 3/20; B05C 11/00; C23C 16/00

(52) U.S. Cl. 73/40.7; 118/712

(57) ABSTRACT

An overall leakage rate of a vacuum system which can be operated continuously or cyclically is determined. The vacuum system includes at least one process chamber (10) and a pumping device (16) connected to the process chamber (10). In a cyclical leakage rate determination technique, the following steps are taken: suppressing a process gas feed to the process chamber (10), feeding a carrier gas to the process chamber (10), conveying the carrier gas and a leakage gas using the pumping device (16), measuring an amount of a gas component in the pumped gas, and determining the overall leakage rate of the vacuum system based on the measured amount of the gas component.

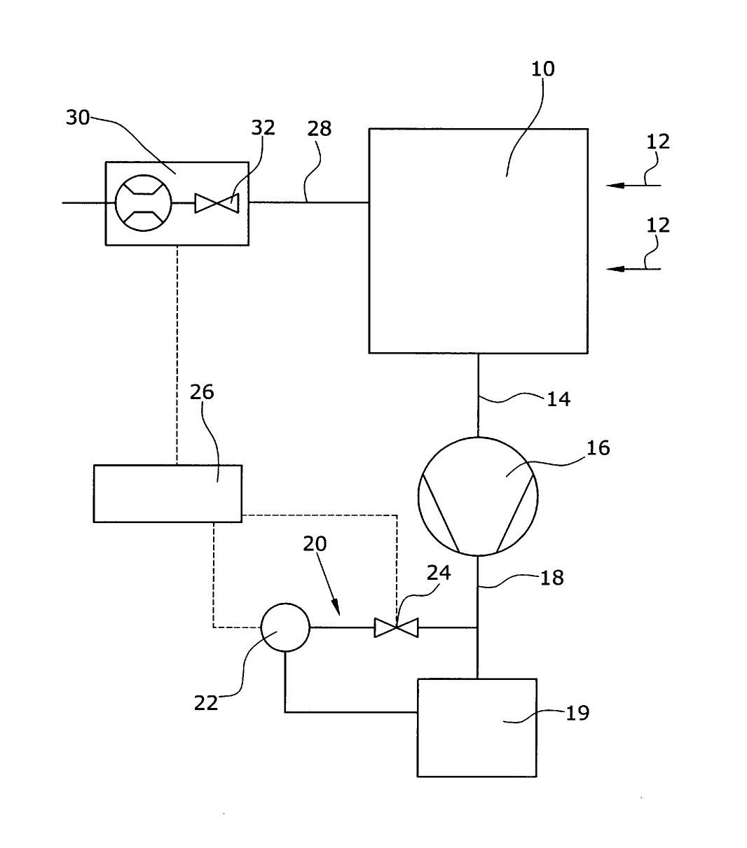

The invention refers to a method for determining the total leak rate of a vacuum system and to a vacuum system for which the method can be performed.

For checking the tightness of individual devices, tightness testing methods using helium leak detection are known. Here, the apparatus to be checked is enclosed in a helium envelope or positioned in a space filled with helium, for instance. It is further known to spray parts of a device to be tested with helium for a local test. Thereafter, the vacuum pump of the apparatus to be tested is operated or the vacuum pump is connected to the apparatus. Then, the helium conveyed by the pump is measured. An integral leak rate of the apparatus can be determined therefrom. These are methods that do allow for a very exact determination of the leak rate, yet, they can be performed economically only with individual smaller apparatus or devices. Examining an entire vacuum system using these methods is only performable within limits. In this context it should be taken into consideration that vacuum systems comprise a plurality of individual apparatus and devices, where an entire vacuum system sometimes may comprise more than fifty, possibly even more than one hundred individual apparatus or components. Moreover. Vacuum systems often comprise large process chambers which may have a volume of more than 10 m³, in particular more than 20 m³, for instance. It is not economically feasible to enclose entire vacuum systems in a helium envelope to then be able to detect the helium pumped by a pump means.

To check the total leak rate of a vacuum system, it is further possible to create a partial vacuum in the process chamber and to close all feed lines connected with the process chamber. Thereafter, the pressure increase in the process chamber is measured over time. Due to the pressure increase and the known volume, a leak rate may be deduced. In this method, only the components upstream of the vacuum pumps are tested. Vacuum pumps and exhaust gas lines are only difficult to test with this method, especially if the volumes are large or different degrees of contamination are to be expected.

Should the process gases be combustible or explosive or should they be corresponding gas mixtures, an exact determination of the oxygen content is necessary, however, to determine explosion or inflammation limits of the medium to be conveyed. This is a security relevant test which requires a corresponding accuracy.

It is an object of the invention to provide a method for determining the total leak rate of a vacuum system, which allows to determine a total leak rate in a simple and, especially, in an economic manner. In particular, the method serves to observe the explosion or inflammation limits of the medium or process gas to be conveyed. It is another object of the invention to provide a vacuum system for which the method can be performed.

The object is achieved, according to the invention, with a method defined in claims 1 and 9, respectively, as well as with a vacuum system defined in claim 15.

The present method for determining the total leak rate of a vacuum system is suited, according to the invention, for use with, in particular, large-volume vacuum systems and/or vacuum systems comprising a plurality of individual devices or apparatus. In particular. These are vacuum systems with a process chamber having a volume of several m³, especially more than 10 m³ or even more than 20 m³ of volume. Further, the method of the invention is particularly suited for systems with a plurality of individual apparatus or instruments or devices, which may number more than fifty, especially more than one hundred. The process chamber is connected with a pump device comprising at least one, usually several vacuum pumps. The vacuum system may be formed by a plurality of process chambers and may possibly comprise a plurality of pumping systems.

An exhaust gas purification system may be provided downstream of the pump means, seen in the flow direction. The exhaust gas purification system cleans the process gases. The vacuum system configured according to the invention further comprises a sensor means such as an oxygen sensor. The same is provided downstream of the pump means, seen in the flow direction, the sensor preferably being as close as possible before the exhaust gas purification system, provided such an exhaust gas purification system exists.

In particular, the sensor may be connected with a control and/or an evaluation means, the same preferably also being connected with regulating valves of the system and serving to control the system.

In a first method for determining the total leak rate of a vacuum system in accordance with the invention, the process gas supply to the vacuum chamber is cut in a first step. For instance, this is achieved by deactivating or closing the process gas supply line or by keeping the supply line closed. An electric valve preferably provided for that purpose is preferably controlled by the control means. In the next step a carrier gas, preferably an inertization gas, is supplied into the process chamber. Nitrogen is the inertization gas of choice. Depending on the sensor used, other gases may also be employed, where it should be noted that a corruption of the measurement by the gas is avoided.

The carrier gas is conveyed by the pump means. Further, the pump means conveys the gas or the air entering into the process chamber due to the leak. The content of a gas component is measured by the sensor arranged downstream of the pump means, seen in the flow direction. Preferably, the oxygen content is measured using an oxygen sensor, since oxygen makes up for the largest part of air. Based on the measured content of the gas component, the total leak rate of the vacuum system is determined. According to the invention, this is preferably possible in a simple manner, since the oxygen content in air of about 21% is known and air enters the system through leaks while pumping the carrier gas. Based on the oxygen content measured or the measured content of another gas component in the air, the total leak rate can be determined in a simple and quick manner, referring, for instance, to tables stored in the control.

Preferably, the flow rate of the carrier gas, i.e. the volume of carrier gas supplied to process chamber per unit time, is known. Thus, an exact calculation of the total leak rate of the vacuum system is possible, especially in an evaluation means to which the corresponding data are supplied directly.

In a particularly preferred embodiment, the oxygen sensor used is an oxygen sensor measuring the oxygen content in % vol. Particularly suitable as oxygen sensors are sensors that measure the oxygen content in % vol. using electrolytic methods. For instance, this may be a sensor designated as “Polytron” from the company Dräger. Such sensors operate reliably in areas where atmospheric pressure substantially prevails. This is true for the preferred arrangement of the sensor downstream of the pump means in the flow direction and upstream of a gas purification system, if provided.

With the flow rate of the carrier gas, in particular a constant flow rate, known or measured by means of a suitable sensor, and with the measured oxygen content in % vol., the total leak rate can be determined in a simple manner either mathematically or by using stored tables. To this end, the conveyed volume of carrier gas is preferably known as well.

When combustible or explosive gases, e.g. H₂, are conveyed, it has to be taken into consideration that the lower explosion limit of hydrogen in air is about 4%. Thus, it has to be made sure that the oxygen concentration in the system does not exceed 0.8% vol. For a known hydrogen gas flow or a known hydrogen content in the process gas, a maximum acceptable air leak in the entire vacuum system is thus obtained. The respective limits will differ depending on the security requirements and when possible additional other explosive or combustible gases or gas mixtures are conveyed.

Depending on an upper limit of the total leak rate of the vacuum system, especially a process-related upper limit, the invention provides for a release of the system only as long as the corresponding upper limit has not been reached. In a preferred embodiment, a corresponding blocking or releasing of the system occurs automatically and may be effected by the existing control.

When defining the upper limit of the gas leak rate or when determining the gas leak rate, gas percentages of the process gas and/or of gases forming during the process are taken into consideration, according to the invention. Thus, it is preferably taken into account that the process gas itself includes oxygen, for example, so that, for instance, an explosive gas mixture will be formed already at lower total leak rates. Further, it is taken into consideration, for instance, that hazardous gases or gas mixtures or, for instance, oxygen can be formed in the process. In a particularly preferred embodiment, this is taken into consideration or included when defining the upper limit of the total leak rate or when determining the total leak rate.

To guarantee for the safety of the vacuum system, the method of the present invention is preferably performed at regular time intervals. Further, it is possible to perform the method before each process start, for instance before each new batch. Possibly, a regular performance and a performance before each process start can be combined. In particular, this depends on the frequency of process starts and the required degree of safety.

Another method for determining the leak rate of a vacuum system in accordance with the present invention is a continuous method. In this case, the vacuum system is configured as described above. In particular, a sensor, preferably an oxygen sensor is arranged downstream of the pump means in the flow direction, and, if provided, upstream of an exhaust gas purification system. In this embodiment of the present method the content of a gas component, especially the oxygen content, is preferably measured in the exhaust gas during the working process, i.e. while a process gas is supplied to the process chamber. Again, the oxygen content is preferably transmitted to an evaluation means. Moreover, the evaluation means knows the components of the process gas or the process exhaust gas, especially a content of oxygen. A total leak rate can be determined therefrom and, in particular, an upper limit of the total leak rate can be defined that should not be exceeded for reasons of safety, so as to avoid the forming of explosive or combustible gas mixtures.

The oxygen content of the process gas or of the process exhaust gas has to be known in order to determine the critical oxygen content for which explosive or combustible gases can be formed. The hydrogen content is either known or may be measured by a separate hydrogen sensor.

Preferably, the oxygen content in % vol. is measured by the oxygen sensor. If the hydrogen content is measured, it is preferably also measured in % vol.

In the continuous method for determining a total leak rate, an alarm signal is issued preferably when a first limit value is exceeded. This may be an acoustic and/or a visual alarm signal. The lower limit value preferably is a limit value at which the process possibly enters a critical range regarding the inflammability or the explosiveness of the gases forming, but the system does not need to be turned off. Preferably, when a second limit value is exceeded, the system is turned off automatically. Here, the second limit value is chosen such that the risk of inflammation or explosion is exceeded, depending on the respective safety requirements.

It is particularly preferred to perform the two above-described methods for a cyclic and a continuous determination of the total leak rate in combination.

The vacuum system suited for the performance of the method is a conventional vacuum system which is merely provided with an additional sensor, in particular an oxygen sensor. Here, the sensor is preferably arranged downstream of the pump means in the flow direction, so that the sensor is situated in particular in a portion of the system where almost atmospheric pressure prevails. Preferably, the sensor is connected with an evaluation means, especially an electronic evaluation means, which immediately calculates the total leak rate depending on the measured content of a gas component, in particular the oxygen content.

In a particularly preferred embodiment the sensor is not arranged in the pipe line immediately connected to the pump means and possibly leading to an exhaust gas purification system, but in a bypass to this pipe line. This is feasible especially in the cyclic method of the invention, since, in this case, the sensor is not continuously subjected to the exhaust gas flow. For this purpose, a valve, especially an electrically controllable valve, may be provided in the bypass branch, which is opened only when the cyclic measuring method is performed.

Preferably, the process chamber of the vacuum system is connected with a carrier gas supply means. The carrier gas supply means may be connected with a flow meter means via a valve. In a preferred embodiment, the valve, preferably an electrically controllable valve, is controllable via the control and evaluation means. Thus, it is possible to perform the cyclic determination method of the invention in a fully automatic manner.

When performing the above described continuous method of the invention, a corresponding flow meter means is preferably provided in the process gas supply line in connection with a preferably electrically controllable valve. Thus, the process gas volume supplied can be measured in a simple manner.

The following is a detailed explanation of the invention with reference to a preferred embodiment.

The schematic drawing illustrates a vacuum system for which the methods of the present invention can be performed.

The vacuum system comprises a process chamber 10 in which a coating process for solar panels is performed, for instance. Through pipe lines indicated by arrows 12, different process gases can be supplied to the process chamber 10. The process chamber 10 is connected with a pump means 16 through a suction line 14. The pump means 16 pumps the process gas from the process chamber 10 and conveys it to an exhaust gas purification system 19 via a line 18.

For the purpose of performing the two methods of the invention an oxygen sensor 22, as well as an electrically controllable valve 24 are provided in a bypass 20. The bypass 20, together with the line 18 downstream of the pump means 16 in the flow direction, is preferably located close to the exhaust gas purification system 19. The bypass 20 directs the branched-off exhaust gas directly to the exhaust gas purification system. The oxygen sensor 22 and the electrically actuatable valve 24 are connected with a control and evaluation means 26.

For the performance of the cyclic method for determining a total leak rate, the process chamber 10 is supplied with carrier gas via a line 28. A flow meter means 30 is arranged in the line 28. The flow meter means 30 has an electrically controllable valve 32. The flow meter means 30 and thus also the valve 32 are connected with the evaluation and control means 26.

When performing the continuous method of the invention for determining a total leak rate, the respective supply lines to the process chamber 10 can be omitted. Instead, it is necessary, however, to measure the gas flows 12. For this purpose, a respective flow meter means may be provided in the process gas supply lines.

For the purpose of performing the cyclic measuring method of the invention, a carrier gas is supplied with a known flow rate to the process chamber 10 via the supply line 28. The carrier gas flow rate supplied is known or may be measured and transmitted to the evaluation means 26. The % vol. of oxygen measured by the oxygen sensor 22 are also transmitted to the evaluation means 26. From this, the evaluation means can determine the integral air leak rate of the system. Since the oxygen content of air is known and is about 21%, the oxygen flow can also be determined therefrom based on the air leak rate.

If, for instance, 100 sccm of carrier gas are supplied to the process chamber and the oxygen sensor shows 6% vol., the integral air leak rate of the system is 40 sccm. For an oxygen content in air of 21%, this makes an oxygen flow of 8.4 sccm. Accordingly, in a continuous method, an air leak rate of a system can be determined based on the value measured by the oxygen sensor, if the process gas flow and, for instance, the oxygen content of the process gas itself and the oxygen created during the process are known.

1. A method for determining the total leak rate of a vacuum system comprising a process chamber and a pump connected with the process chamber, the method comprising the following steps:
stopping the process gas supply to the process chamber,
supplying a carrier gas to the process chamber,
conveying the carrier gas and a leak gas using the pump means,
measuring a content of a gas component of the gas conveyed by the pump, and
determining the total leak rate of the vacuum system on the basis of the measured content of the gas component.

2. The method of claim 1, wherein the carrier gas is supplied to the process chamber at a constant known flow rate.

3. The method of claim 1, wherein the content of the gas component is measured in % vol.

4. The method of claims 1, wherein:
the carrier gas used is an inertizing gas, and/or
an oxygen content of the carrier gas is measured.

5. The method of claim 1, wherein the vacuum system is not released for production when an upper limit of the total leak rate is exceeded.

6. The method of claim 5, wherein gas proportions of the process gas and/or gases created during the process are taken into account when defining the upper limit of the total leak rate or when determining the total leak rate.

7. The method of claim 6, wherein the process gases taken into account are oxygen and/or combustible gases.

8. The method of claim 1, wherein the method is performed at regular time intervals and/or before each process start.

9. A method for determining a total leak rate of a vacuum system comprising a process chamber and a pump connected with the process chamber, the method comprising the following steps:
measuring a content of a gas component during a working process, and
determining a total leak rate of the vacuum system based on the measured content of the gas component and a process gas flow.

10. The method of claim 9, wherein oxygen in the gas component is measured and/or a hydrogen content of the process gas is known.

11. The method of claim 9, wherein an oxygen content is measured in % vol. and/or a hydrogen content is measured in % vol.

12. The method of claim 9, wherein an alarm signal is generated when a first limit value is exceeded and/or the vacuum system is turned off automatically when a second limit value is exceeded.

13. The method of claim 9, wherein the measured content of the gas component is determined downstream of the pump in the flow direction.

14. A method for a cyclic determination of a total leak rate of a vacuum system of claim 1, wherein the method for a continuous determination of the total leak rate of the vacuum system of claim 9 is performed during the production process.

15. A vacuum system in which the method of claim 1 is performed, comprising:
a process chamber,
a pump means connected with the process chamber,
a sensor which determines a content of a gas component, arranged downstream of the process chamber in the flow direction, and
an evaluation component which determines a total leak rate connected with said sensor.

16. The vacuum system of claim 15, wherein the sensor is arranged in a branch such as a bypass of a pipe line connected with an outlet of the pump.

17. The vacuum system of claim 15, further including:
an exhaust gas purification system arranged downstream of the pump in the flow direction, the sensor being arranged upstream of the purification system.

18. The vacuum system of claim 15, further including:
a carrier gas supply connected with the pump chamber.

19. A vacuum system in which the method of claim 9 is performed, comprising:
a process chamber,
a pump means connected with the process chamber,
a sensor which determines a content of a gas component, arranged downstream of the process chamber in the flow direction, and
an evaluation component which determines a total leak rate connected with said sensor.

20. A vacuum system comprising:
a process chamber;
a vacuum pump which pumps gas from the process chamber;
a sensor which measures a selected gas component in the gas pumped from the process chamber by the vacuum pump;
an evaluation component which determines a total leak rate of the vacuum system based on the measured gas component in the gas pumped from the process chamber by the vacuum pump.
